(19) United States
(12) Patent Application Publication
(10) Pub. No.: US 2006/0022355 A1
(43) Pub. Date: Feb. 2, 2006

(54) Power module and electric transportation apparatus incorporating the same

(76) Inventors: Takayuki Murai, Shizuoka (JP); Koji Morita, Shizuoka (JP)

Correspondence Address: YAMAHA HATSUDOKI KABUSHIKI KAISHA;C/O KEATING & BENNETT, LLP, 8180 GREENSBORO DRIVE, SUITE 850, MCLEAN, VA, 22102, US

(21) Appl. No.: 11/189,046

(22) Filed: Jul. 25, 2005

(30) Foreign Application Priority Data
Jul. 29, 2004 (JP) 2004-221170

(51) Int. Cl. H01L 29/76

(52) U.S. Cl. 257/787

(57) ABSTRACT

A power module includes a plurality of first semiconductor devices disposed so as to define a first layer in a substantially common plane, a plurality of second semiconductor devices disposed so as to define a second layer in a substantially same plane, and at least one metal plate electrically connected to at least two semiconductor devices selected from among the plurality of first and second semiconductor devices. The first layer and second layer are stacked such that the plurality of second semiconductor devices do not overlap the plurality of first semiconductor devices.

### BACKGROUND OF THE INVENTION

1. Field of the Invention

The present invention relates to a power module and an electric transportation apparatus including the same. More particularly, the present invention relates to a power module for supplying power to a motor which is used as a driving mechanism of a transportation apparatus, and an electric transportation apparatus including such a power module.

2. Description of the Related Art

In recent years, transportation apparatuses which utilize an electric motor (hereinafter simply referred to as a “motor”) as a driving mechanism have been drawing attention, due to concerns about environmental or energy issues, etc. As compared to an internal combustion engine, a motor is advantageous in that it produces little operating noise while being operated, and permits a great amount of design freedom in its outer shape, thus enabling the motor to be installed close to a driving mechanism. Therefore, with a motor, it is possible to realize a novel transportation apparatus having features which do not pertain to transportation apparatuses incorporating conventional internal combustion engines. From such perspectives, development activities are being directed to transportation apparatuses incorporating motors.

A transportation apparatus incorporating a motor includes a power module (a power semiconductor apparatus) which supplies power to the motor and controls the revolutions of the motor. FIG. 1 is a circuit diagram disclosed in Japanese Laid-Open Patent Publication No. 2002-262593, in which a conventional power module is included. As shown in FIG. 1, power which is supplied from a battery 12 is converted to an appropriate driving power by a power module 10 shown by a broken line, and supplied to a motor 14. As shown in FIG. 1, the power module 10 includes a speed control circuit 20, a smoothing capacitor 22, a plurality of FETs (field-effect transistors) 16, and a plurality of diodes 18.

FIGS. 2A and 2B are, respectively, a plan view and a side view showing the power module 10, whose component elements other than the speed control circuit 20 are formed on a printed wiring board. As shown in FIGS. 2A and 2B, the power module 10 includes a printed wiring board 40, having a surface on which conductive regions 40a, 40b, 40c, and 40d are formed. The conductive region 40c includes a plurality of subregions, with resistors being connected between subregions.

FETs and diodes which are used in such a power module are likely to increase in temperature due to a large current flowing therethrough. In order to avoid failure, such FETs and diodes (power FETs and diodes) need to have a high heat-releasing ability. Therefore, FETs and diodes for use in a power module are directly bonded to the conductive pattern surface of the circuit board, in order to realize good heat-releasing characteristics.

Specifically, each FET 16 is soldered to the conductive pattern 40b so that its drain electrode is in contact with the conductive pattern 40b. A gate electrode of each FET 16 is connected to a conductive pattern 40c via a wire 42b composed of aluminum. A source electrode of each FET 16 is connected to the conductive pattern 40d via two wires 42a. Furthermore, a source electrode of each FET 16 is connected to the conductive pattern 40c via a wire 42c. On the other hand, each diode 18 is soldered to the conductive pattern 40a so that its cathode electrode is in contact with the conductive pattern 40a. An anode electrode of each diode 18 is connected to the conductive pattern 40b via wires 41a composed of aluminum.

In the power module shown in FIGS. 2A and 2B, a large current flows through the conductive pattern 40b, to which the FETs 16 are soldered. Therefore, it is necessary to increase the width of the conductive pattern 40b so as to reduce the resistance of the conductive pattern 40b. However, doing so will require an increase in the length of the wires 42a connected to the FETs 16, which in turn will cause heating problems associated with the wire resistance. For example, if three wires each having a diameter of 0.5 mm and a length of 15 mm are connected in a parallel connection, there is a wire resistance of 0.7 mΩ across the two ends of the parallel connection. If a current of 100 A is flowed between these two ends, a heat of 7.0 W is generated in the wires, so that the wires may reach a temperature of 200° C. or more, for example. The generated heat is transmitted to the FETs 16, thus increasing the temperature of the FETs 16. Thus, the maximum large current value which can be flowed through the power module is limited to a value which will not invite a degree of heating such that the wires 42a and the FETs 16 are deteriorated.

In theory, heating of the wires 42a may be counteracted in several ways. For example, the number of wires connecting each FET 16 to a conductive region may be increased to reduce resistance, thus minimizing the amount of generated heat. However, the number of wires that can be connected to an FET 16 is limited by the size of each electrode of the FET 16, and thus it is impossible to connect too many wires to the FET 16. Moreover, ultrasonic waves are used for the wire connecting process. Any increase in the number of wires or the wire thickness will result in an increased bonding area, and consequently, the ultrasonic waves may damage the FETs, possibly reducing the reliability of the FETs.

It may be possible to use two conductive layers for the printed wiring board to increase the layout flexibility of the conductive regions and the FETs and diodes on the printed wiring board. In this manner, each electrode of each FET may be placed close to a conductive pattern, thus reducing the length of the wire connecting the electrode to the conductive pattern. However, in this case, it also becomes necessary to provide an insulating layer for the printed wiring board in order to realize insulation between the two conductive layers. Since an insulating layer generally has a poor thermal conductivity, the addition of the insulating layer will result in a reduced heat-releasing ability of the printed wiring board, thus lowering the efficiency with which the heat generated in the FETs and wires is dissipated to the exterior via the printed wiring board.

Alternatively, it may be possible to use a printed wiring board with a single thick conductive layer to reduce the width of any conductive pattern across which a wire must be extended. In this case, however, the thickness of the conductive layer may make it difficult to perform patterning by etching or the like.

Japanese Laid-Open Patent Publication No. 2004-47850 discloses a power semiconductor device which lacks wire connections with a main purpose of preventing wire breaks. In this power semiconductor device, electrodes are used to provide electrical connections to a pair of transistors which compose a functional portion, which is associated with one phase, of a three-phase inverter. This laid-open patent publication describes that omission of wires will make it possible to solve the problems associated with wire connections.

However, in accordance with the power semiconductor device disclosed in Japanese Laid-Open Patent Publication No. 2004-47850, electrical connections to the transistors that are associated with only one phase are realized by electrodes. Therefore, in order to construct a three-phase inverter, electrical connection elements will be required for realizing interconnections between the three phases. Moreover, although Japanese Laid-Open Patent Publication No. 2004-47850 discloses using a thin film circuit pattern to realize such electrical connections, a thin film circuit pattern cannot be considered as having a sufficiently low resistance as compared to that of a conventional wire. Therefore, there is a possibility that the problems associated with heating may not be solved.

### SUMMARY OF THE INVENTION

In order to overcome the problems of conventional power modules described above, preferred embodiments of the present invention provide a power module which does not induce much heating, and which is thus reliable or capable of allowing a large current to be flowed therethrough.

A power module according to a preferred embodiment of the present invention includes a plurality of first semiconductor devices disposed so as to form a first layer in a substantially common plane, a plurality of second semiconductor devices disposed so as to form a second layer in a substantially common plane, and at least one metal plate electrically connected to at least two semiconductor devices selected from among the plurality of first and second semiconductor devices, wherein the first layer and second layer are stacked in such a manner that the plurality of second semiconductor devices do not overlap the plurality of first semiconductor devices.

In a preferred embodiment of the present invention, the at least one metal plate includes first, second, and third metal plates, and the first, second, and third metal plates are disposed such that the plurality of first semiconductor devices defining the first layer are interposed between the first and second metal plates, and such that the plurality of second semiconductor devices defining the second layer are interposed between the second and third metal plates.

In a preferred embodiment of the present invention, the first, second, and third metal plates are preferably made of a material selected from the group consisting of copper, aluminum, and stainless steel.

In a preferred embodiment of the present invention, the first and second semiconductor devices are disposed so as to alternate on a surface of projection that is substantially perpendicular to a direction in which the first layer and the second layer are stacked.

In a preferred embodiment of the present invention, the second metal plate is connected, on a front surface thereof, to at least one of the plurality of first semiconductor devices, and the second metal plate is connected, on a back surface thereof, to at least one of the plurality of second semiconductor devices.

In a preferred embodiment of the present invention, the power module further includes a package for enclosing the first, second, and third metal plates and the plurality of first and second semiconductor devices in an integral manner.

In a preferred embodiment of the present invention, each of the plurality of first and second semiconductor devices includes a plurality of pads for establishing external electrical connections, and the plurality of pads include a large current pad to or from which a large current is applied or taken out, and a control signal pad to which a control signal is applied, the large current pad being connected to the first, second, or third metal plate.

In a preferred embodiment of the present invention, the power module further includes a large current terminal connected to the first, second, or third metal plate, and a control signal terminal connected to the control signal pad.

In a preferred embodiment of the present invention, the power module further includes a passive element electrically connected to the control signal terminal.

In a preferred embodiment of the present invention, the first, second, and third metal plates have a thickness in a range from about 0.5 mm to about 2 mm.

In a preferred embodiment of the present invention, the plurality of first and second semiconductor devices are a plurality of MOS-FETs.

In a preferred embodiment of the present invention, the power module has three first semiconductor devices and three second semiconductor devices, and constitutes a three-phase inverter circuit for driving a motor.

Alternatively, a power module according to another preferred embodiment of the present invention includes a first metal plate, a plurality of second metal plates opposing the first metal plate, a plurality of first semiconductor devices interposed between the first metal plate and the plurality of second metal plates, a third metal plate opposing the plurality of second metal plates, the third metal plate being disposed opposite to the first metal plate with respect to the plurality of second metal plates, a plurality of second semiconductor devices interposed between the third metal plate and the plurality of second metal plates, and a package enclosing the first metal plate, the plurality of first semiconductor devices, the plurality of second metal plates, the plurality of second semiconductor devices, and the third metal plate, wherein the first metal plate is connected to the plurality of first semiconductor devices, each of the plurality of second metal plates is connected to at least one of the plurality of first semiconductor devices and at least one of the plurality of second semiconductor devices, the third metal plate is connected to the plurality of second semiconductor devices, and the plurality of second semiconductor devices are disposed so as not to overlap the plurality of first semiconductor devices.

A motor control unit according to another preferred embodiment of the present invention includes one of the power modules according to any of the preferred embodiments of the present invention described above, and a control circuit arranged to output a control signal to the plurality of first and second semiconductor devices.

An electric transportation apparatus according to a further preferred embodiment of the present invention includes the motor control unit according to the preferred embodiment of the present invention described in the preceding paragraph, a motor connected to the motor control unit, and a battery for supplying power to the motor control unit.

A method of producing a power module according to the present invention includes a step (A) of affixing a plurality of first semiconductor devices each having a pad on an upper surface and a pad on a lower surface for establishing external electrical connections, to a first lead frame having a frame to which a first metal plate is connected, in such a manner that one of the pad on the upper surface and the pad on the lower surface is in contact with the first metal plate, a step (B) of affixing a second lead frame having a frame to which a second metal plate is connected, to the plurality of first semiconductor devices, in such a manner that the other of the pad on the upper surface and the pad on the lower surface of each of the plurality of first semiconductor devices is in contact with the second metal plate, a step (C) of placing a plurality of second semiconductor devices each having a pad on an upper surface and a pad on a lower surface for establishing external electrical connections, on a surface of the second metal plate to which the plurality of first semiconductor devices are not bonded, in such a manner that the plurality of second semiconductor devices do not overlap the plurality of first semiconductor devices, and affixing the plurality of second semiconductor devices in such a manner that one of the pad on the upper surface and the pad on the lower surface is in contact with the second metal plate, a step (D) of affixing a third lead frame having a frame to which a third metal plate is connected, to the plurality of second semiconductor devices, in such a manner that the other of the pad on the upper surface and the pad on the lower surface of each of the plurality of second semiconductor devices is in contact with the third metal plate, and a step (E) of cutting the first, second, and third metal plates off of the corresponding frames.

In a preferred embodiment of the present invention, the frames of the first, second, and third lead frame have identical shapes, and by aligning the frames of the first, second, and third lead frames with one another, the first, second, and third metal plates are positioned with respect to the plurality of first and second semiconductor devices.

In a preferred embodiment of the present invention, at steps (A), (B), (C), and (D), the affixation is performed by using solder paste, and between step (D) and step (E), the method further includes a step (F) of performing a heat treatment to melt and solidify the solder paste.

In a preferred embodiment of the present invention, between step (F) and step (E), the method further includes step (G) of forming via molding a package enclosing the first, second, and third metal plates and the plurality of first and second semiconductor devices in an integral manner.

In a preferred embodiment of the present invention, the pads of each of the plurality of first and second semiconductor devices include a large current pad to or from which a large current is applied or taken out, and a control signal pad to which a control signal is applied, and at least one of the first, second, and third lead frames include a control signal terminal which is connected to the frame so as to be connected to the control signal pad.

In a preferred embodiment of the present invention, a bump is formed on the control signal pad, and the bump is connected to the control signal terminal.

In a preferred embodiment of the present invention, wherein the control signal terminal includes an insulating film covering any region other than a region to be in contact with the control signal pad.

In accordance with the power module according various preferred embodiments of the present invention, electrical connections to semiconductor devices are realized preferably by metal plates. Therefore, as compared to a conventional power module in which wires are used, the semiconductor devices can be electrically connected with a low resistance, and heat loss at the electrical connection elements can be reduced. Moreover, in accordance with the power module of the present invention, the semiconductor devices are stacked so as not to overlie one another. This prevents concentration of the heat generated in the semiconductor devices due to overlapping of elements, and permits uniform radiation of the heat within the overall power module. Thus, malfunctioning and/or deterioration of the semiconductor devices due to local concentration of heat are minimized, whereby the reliability of the overall power module is enhanced.

Other features, elements, processes, steps, characteristics and advantages of the present invention will become more apparent from the following detailed description of preferred embodiments of the present invention with reference to the attached drawings.

### BRIEF DESCRIPTION OF THE DRAWINGS

FIG. 1 is a circuit diagram showing a driving system including a conventional power module.

FIGS. 2A and 2B are a plan view and a side view, respectively, showing the conventional power module of FIG. 1.

FIG. 3 is a circuit diagram schematically showing a driving system including a power module according to a preferred embodiment of the present invention.

FIG. 4 is a circuit diagram showing, in a power module, a passive element with which to control the timing of switching a motor.

FIGS. 5A and 5B are an upper plan view and a lower plan view, respectively, showing a transistor used as a power semiconductor device in a power module according to a preferred embodiment of the present invention.

FIG. 6A is an upper plan view showing a power module according to a preferred embodiment of the present invention. FIGS. 6B and 6C are side views of the power module as seen from two different directions.

FIG. 7 is a cross-sectional view showing a cross-sectional structure of a power module according to a preferred embodiment of the present invention, taken along line 7A-7A′ in FIG. 6A.

FIG. 8 is a side view showing a motor control unit according to a preferred embodiment of the present invention.

FIGS. 9A, 9B, and 9C are plan views showing lead frames used in the production of a power module according to a preferred embodiment of the present invention.

FIGS. 10A and 10B are a plan view and a side view, respectively, showing a power module according to a preferred embodiment of the present invention during production thereof.

FIGS. 11A, 11B, and 11C are diagrams showing insulation methods between a terminal to be connected to a gate pad and a source pad.

FIGS. 12A and 12B are a plan view and a side view, respectively, showing a power module according to a preferred embodiment of the present invention during production thereof.

FIGS. 13A and 13B are a plan view and a side view, respectively, showing a power module according to a preferred embodiment of the present invention during production thereof.

FIGS. 14A and 14B are a plan view and a side view, respectively, showing a power module according to a preferred embodiment of the present invention during production thereof.

FIGS. 15A and 15B are a plan view and a side view, respectively, showing a power module according to a preferred embodiment of the present invention during production thereof.

FIGS. 16A and 16B are a plan view and a side view, respectively, showing a power module according to a preferred embodiment of the present invention during production thereof.

FIGS. 17A and 17B are a plan view and a side view, respectively, showing a power module according to a preferred embodiment of the present invention during production thereof.

FIG. 18 is a diagram illustrating an electric vehicle according to a preferred embodiment of the present invention.

### DETAILED DESCRIPTION OF PREFERRED EMBODIMENTS

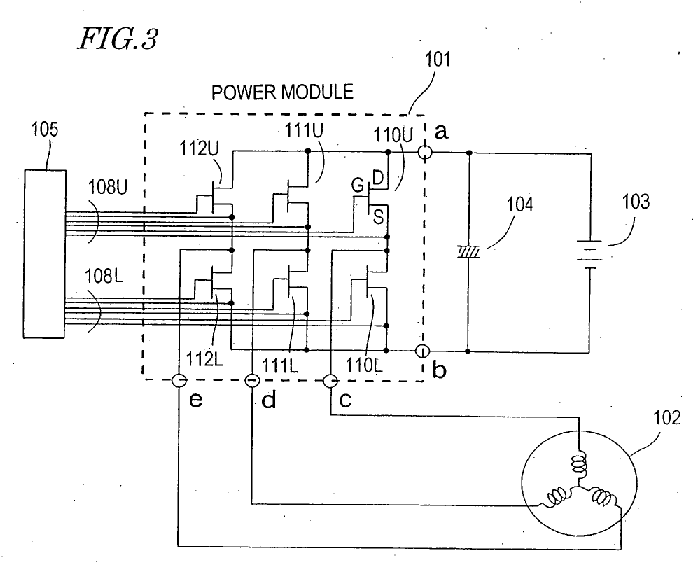

Hereinafter, preferred embodiments of the present invention will be described with reference to the accompanying drawings. FIG. 3 is a circuit diagram schematically showing a driving system of a transportation apparatus incorporating a power module according to a preferred embodiment the present invention. The power module according to various preferred embodiments of the present invention can be used in a variety of transportation apparatuses which utilize a motor as a driving mechanism. In the present specification, a “power module” is defined as any device which supplies a large current (10 A or more) to a motor or the like while controlling the current by using a semiconductor device.

As shown in FIG. 3, the transportation apparatus preferably includes a power module 101, a motor 102, a battery 103, a smoothing capacitor 104, and a control circuit 105. In the present preferred embodiment, the motor 102 is preferably a brush-less DC motor. To the three terminals of the motor 102, a three-phase current having phases which are 120° apart from one another is applied, whereby the motor 102 is driven. The power module 101 and the control circuit 105 define a motor control unit including a three-phase inverter circuit.

The battery 103 is connected in parallel to a smoothing capacitor 104 for smoothing out voltage fluctuations, and connected to terminals a and b of the power module 101 in order to supply power to the power module 101. The power module 101 receives DC voltage power from the battery 103, and generates driving power which is suitable for driving the motor 102. Since the motor 102 is to be driven with a three-phase current, the power module 101 generates a three-phase current from the DC current.

For this purpose, between the terminals a and b of the power module 101, three current paths are formed, each of which is composed of a series connection of two field-effect transistors. In other words, the power module 101 includes six field-effect transistors 110U, 110L, 111U, 111L, 112U, and 112L as power semiconductor devices (i.e., semiconductor devices for performing switching operation for controlling the current supply).

The field-effect transistors 110U and 110L, which are series-connected to each other, define a current path for one phase. The field-effect transistors 111U and 111L, which are series-connected to each other, define a current path for another phase. The field-effect transistors 112U and 112L, which are series-connected to each other, define a current path for still another phase. The field-effect transistors 110U, 111U, and 112U, which are connected to the higher-potential side of the battery 103, are referred to as the “upper arms” for the respective phases. The field-effect transistors 110L, 111L, and 112L, which are connected to the lower-potential side of the battery 103, are referred to as the “lower arms” for the respective phases.

Although the present preferred embodiment illustrates an example where MOS type field-effect transistors (hereinafter simply referred to as “transistors”) are preferably used as the power semiconductor devices (switching elements), bipolar transistors or any other transistors may instead be used as the power semiconductor devices. Other than transistors, any power semiconductor devices capable of allowing a large current (e.g., about 10 A or more) to be applied thereto, e.g., diodes or thyristors, may also be used. Furthermore, although the present preferred embodiment illustrates a case where the upper arm and the lower arm for each phase are each composed of a single power semiconductor device, it will be appreciated that the upper arm and the lower arm may each be composed of a plurality of power semiconductor devices.

To a gate G and a source S of each of the transistors 110U to 112U and the transistors 110L to 112L, control signals which are generated by the control circuit 105 are applied via electrical connection elements 108U and 108L. On the basis of the control signals, each transistor performs switching operations. For example, each transistor 110 is rapidly switched with a frequency based on pulse width modulation (PWM), whereby a three-phase current is generated and applied to the motor 102 via the terminals c, d, and e.

In order to adjust the timing of switching each of the transistors 110U to 112U and the transistors 110L to 112L and generate a three-phase current having a desired profile, passive elements 122 for timing controlling purposes may be connected to the gate G of each transistor, as shown in FIG. 4. In the example shown in FIG. 4, a diode D1 and resistors R1 and R2 are connected to the gate G of each transistor. Moreover, in order to permit an electric charge stored in the transistor to be discharged while the transistor is in an off state, a resistor R3 may be connected between the gate G and the source S, as shown in FIG. 4. Note that these passive elements may be included in the control circuit 105. However, in the case where the influences of parasitic capacitances and parasitic resistances associated with electrical connections may become problems, these passive elements are preferably connected in a physically close location to each transistor.

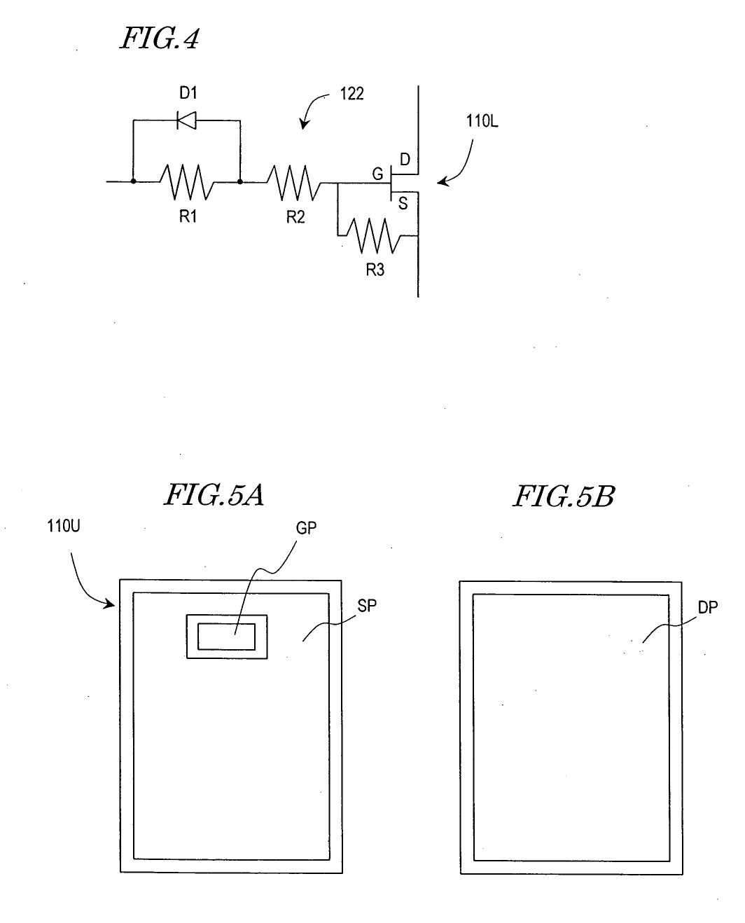

The specific structure of each transistor will be described with reference to FIGS. 5A and 5B, which are an upper plan view and a lower plan view, respectively, showing the transistor 110U. The transistor 110U is a preferably chip having a substantially rectangular solid shape and opposing upper and lower surfaces. On one of the upper or lower surfaces, the transistor 110U has a source pad SP connected to the source and a gate pad GP connected to the gate. On the other surface, the transistor 110U has a drain pad DP connected to the drain. In the present specification, these pads for allowing the transistor 110U to be electrically connected to external elements will be classified into either a “large current pad” (which is used for applying or taking out a large current) and a “control signal pad” (which is used for applying a control signal) The gate pad GP functions as a control signal pad. The drain pad DP functions as a large current pad. The source pad SP functions as both a control signal pad and a large current pad. The other transistors 111U to 112U and 110L to 112L also preferably have the same structure.

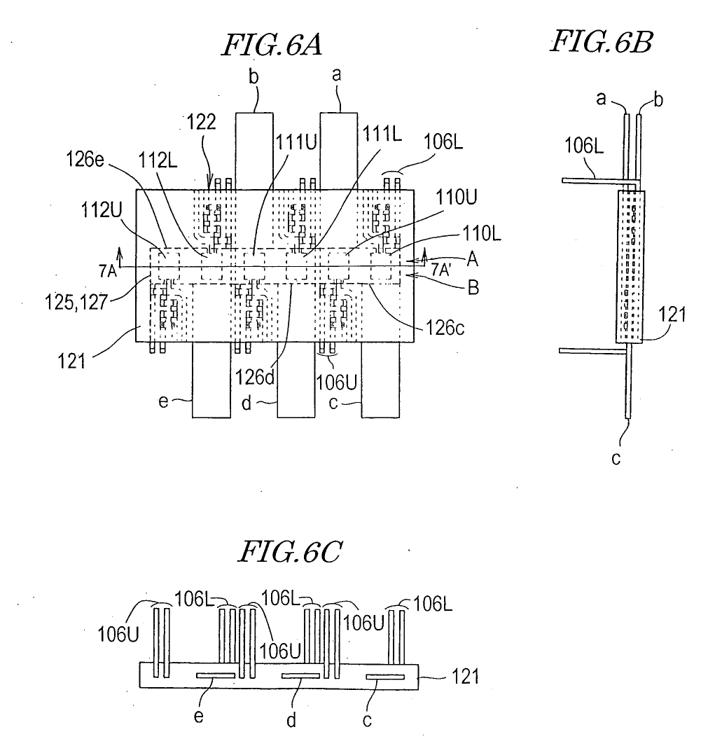

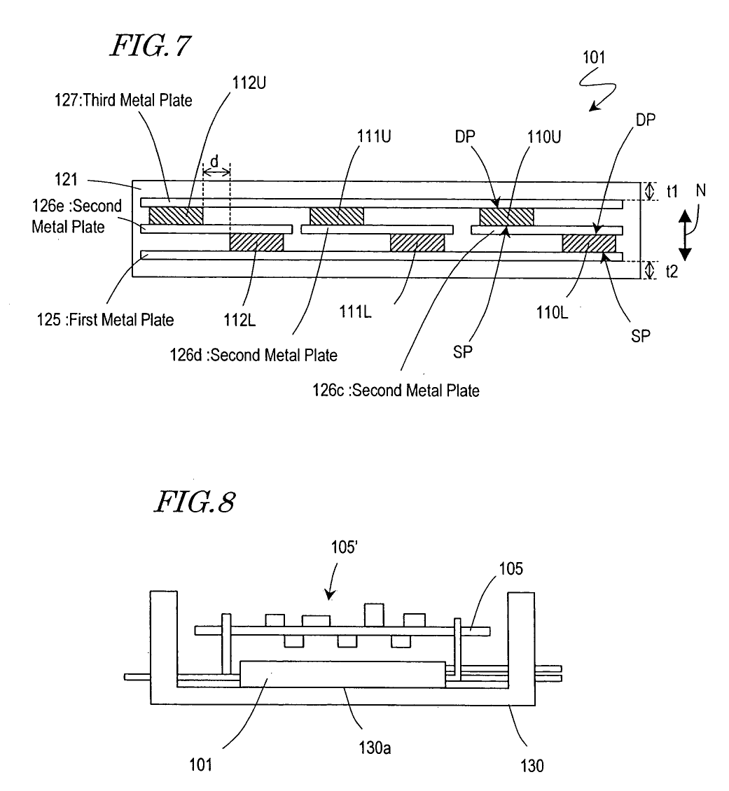

Next, with reference to FIGS. 6A to 6C and FIG. 7, the structure of the power module 101 will be described more specifically. FIGS. 6A to 6C are an upper plan view and two side views (from two different directions) showing the power module 101 as implemented in one package. FIG. 7 is a cross-sectional view taken along line 7A-7A′ in FIG. 6A. In FIGS. 6A and 6B, the internal structural elements of the power module 101 are shown with broken lines.

As shown in these figures, the power module 101 includes six transistors 110U to 112U, 110L to 112L. Furthermore, as best shown in FIG. 7, the power module 101 includes a first metal plate 125, second metal plates 126c, 126d, and 126e, and a third metal plate 127.

The transistors 110L to 112L defining the lower arms of the respective phases are interposed between the first metal plate 125 and the second metal plates 126c, 126d, and 126e, respectively, and are disposed within the same plane so as to constitute a single layer (herein referred to as a “first layer” for convenience). The transistors 110U to 112U defining the upper arms of the respective phases are interposed between the third metal plate 127 and the second metal plates 126c, 126d, and 126e, respectively, and are disposed within the same plane so as to constitute a single layer (herein referred to as a “second layer”) that is different from the first layer. In other words, the following layers are stacked in this order: the first metal plate 125; the first layer composed of the transistors 110L to 112L; the second metal plates 126c to 126e; the second layer composed of the transistors 110U to 112U; and the third metal plate 127.

As is clearly shown in FIGS. 6A and 7, the first layer and the second layer are stacked in such a manner that the transistors 110U to 112U defining the upper arm do not appear to overlap with the transistors 110L to 112L defining the lower arm when viewed in a direction (shown by an arrow N in FIG. 7) that is substantially perpendicular to the principal surface of each metal plate. The upper arm transistor and the lower arm transistor of each phase are positioned in such a manner that the adjacent ends thereof are spaced apart from each other by a predetermined distance d when viewed in a direction N that is substantially perpendicular to the principal surface of each metal plate.

In the present preferred embodiment, as shown in FIG. 6A, within a surface of projection extending substantially perpendicularly to the stacking direction (which coincides with the direction N that is substantially perpendicular to the principal surface of each metal plate) of the first and second layers, i.e., within a surface of projection which lies substantially parallel to the principal surface of each metal plate, the transistors 110U to 112U defining the upper arm and the transistors 110L to 112L defining the lower arm appear to alternate with one another. In other words, in a certain cross section that is substantially perpendicular to the principal surface of each metal plate, the upper arm transistors 110U to 112U and the lower arm transistors 110L to 112L appear to be arranged in staggered positions as shown in FIG. 7.

The first metal plate 125 functions as an electrical connection element for interconnecting the sources of the transistors 110L to 112L defining the lower arms in FIG. 3. The third metal plate 127 functions as an electrical connection element for interconnecting the drains of the transistors 110U to 112U defining the upper arms of the respective phases. Each of the second metal plates 126c, 126d, and 126e functions as an electrical connection element for connecting the source of the transistor defining the upper arm of each phase to the drain of the transistor composing the lower arm of that phase.

As shown in FIG. 5, each transistor has a source pad SP and a drain pad DP respectively disposed on the two opposing principal surfaces thereof. In the power module 101, each such pad of each transistor is directly bonded to a corresponding metal plate via solder or other suitable material. More specifically, the source pads SP of the transistors 110L to 112L defining the lower arms are bonded to the first metal plate 125. The drain pads DP of the transistors 110L to 112L are bonded to the back surfaces of the second metal plates 126c, 126d, and 126e, respectively. On the other hand, the source pads SP of the transistors 110U to 112U defining the upper arms are bonded to the front faces of the second metal plates 126c, 126d, and 126e, respectively. The drain pads DP of the transistors 110U to 112U are bonded to the third metal plate 127.

As shown in FIGS. 6A and 6B, terminals b and a are integrally formed on and connected to the first metal plate 125 and the third metal plate 127, respectively. As shown in FIGS. 6A and 6C, terminals c, d, and e are integrally formed on and connected to the second metal plates 126c, 126d, and 126e, respectively. Each of the terminals a to e has a broad width in order to allow the power module 101 to be connected to the battery 103 and to the motor 102 with a low resistance, thus allowing a large current to flow therethrough.

The first, second, and third metal plates 125, 126c to 126e, and 127, as well as the transistors 110U to 112U and the transistors 110L to 112L, are integrally sealed with a package 121 which is molded from a resin or other suitable material. The terminals a, b, c, d, and e extend outside of the package 121.

The package 121 provides insulation between the metal plates and the transistors, and serves to fix the terminals in place. As shown in FIG. 7, the regions between the first metal plate 125 and the second metal plates 126c to 126e where the transistors 110L to 112L are not present are filled with the material of the package 121. Similarly, the regions between the third metal plate 127 and the second metal plates 126c to 126e where the transistors 110U to 112U are not present are also filled with the material of the package 121. Therefore, each of the transistors 110L to 112L opposes a layer of package material (e.g., a resin layer) which is present between the third metal plate 127 and a corresponding one of the second metal plates 126c to 126e. Each of the transistors 110U to 112U opposes a layer of package material which is present between the first metal plate 125 and the second metal plates 126c to 126e. Thus, by ensuring that the transistors 110U to 112U do not respectively oppose the transistors 110L to 112L (via the metal plates) but are offset therefrom, heat is promptly dissipated to the outside without being detained in between the transistors. Furthermore, since the interspaces between metal plates are filled with a package material such as a resin, heat dissipation is further enhanced.

Preferably, the package 121 is formed of a material which is insulative and airtight so that the internal structure is prevented from corrosion. As the material of the package 121, a thermosetting resin such as an epoxy resin used for semiconductor IC packages can be suitably used.

The heat which is generated in the metal plates and the transistors is dissipated to the outside via the package 121. Therefore, a thickness t2 from the outer surface of the package 121 to the first metal plate 125 (which is filled with a package material such as a resin) and the thickness t1 from the outer surface of the package 121 to the third metal plate 127 (similarly filled with a package material such as a resin) are preferably small. However, the package 121 needs to protect the metal plates and the transistors and support the entire power module 101 with a predetermined mechanical strength. Therefore, the optimum thicknesses t1 and t2 are to be selected while paying attention to the fact that the overall mechanical strength must be ensured.

In order to control each transistor in the power module 101, a control signal which is output from the control circuit 105 shown in FIG. 3 must be applied to the gate and the source of each transistor. Therefore, corresponding to the electrical connection elements 108U and 108L shown in FIG. 3, the power module 101 further includes control signal terminals 106U and 106L which are connected to each transistor as shown in FIG. 6C.

Each control signal terminal 106U is connected to the source and gate of a corresponding one of the transistors. 110U to 112U. Each control signal terminal 106L is connected to the source and the gate of a corresponding one of the transistors 110L to 112L. In the case where passive elements 122 for timing controlling purposes (mentioned earlier) are to be connected to the gate electrode of each transistor, such passive elements 122 are preferably connected near the connection between the transistor and the control signal terminal 106U or the control signal terminal 106L. Such passive elements 122 are to be provided within the package 121.

As shown in FIGS. 6A to 6C, the control signal terminals 106U and 106L in the present preferred embodiment are bent after protruding outside of the package 121. Thus, by ensuring that the control signal terminals 106U and 106L are led in different directions from the directions in which the terminals a, b, c, d, e are led, electrical connection from the control circuit 105 to the control signal terminals 106U and 106L can be facilitated. Depending on the manner of electrical connections to the control circuit 105, the battery 103, and/or the motor 102 to be connected to the power module 101, the terminals a, b, c, d, and e may be bent, and the control signal terminals 106U and 106L may be led straightforwardly, conversely to the example shown in FIGS. 6A to 6C. Alternatively, these terminals may not be bent at all.

As described earlier, the first, second, and third metal plates 125, 126c to 126e, and 127 are connected to the source or drain of each transistor, so that a large current will flow therethrough. Therefore, it is preferable that the first, second, and third metal plates 125, 126c to 126e, and 127 have a low resistance. Specifically, the first, second, and third metal plates 125, 126c to 126e, and 127 are preferably formed from a low-resistance metal such as copper, aluminum, or stainless steel.

Moreover, it is preferable that each metal plate has a thickness of about 0.5 mm or more. If the metal plate is thinner than about 0.5 mm, the metal plate may have a high resistance, and considerable heating may occur in response to a large current flow. From the perspective of resistance, it is preferable that each metal plate is as thick as possible, with no particular upper limits. However, when taking into consideration the processibility of the metal plate when implementing the power module 101 as a package, it is preferable that each metal plate has a thickness of about 2 mm or less. As will be described in detail later, by setting the thickness of each metal plate to be about 2 mm or less, it becomes possible to suitably use lead frames to form such metal plates and produce the power module 101.

The width of each metal plate, as taken along a direction that is substantially perpendicular to the longitudinal direction thereof, is also contributive to resistance reduction. Since the first, second, and third metal plates 125, 126c to 126e, and 127 are bonded to transistors, it is preferable that each such metal plate is at least equal in width to or wider than the outer shape of the corresponding transistor. In terms of metal plate resistance alone, it is true that the wider a metal plate is, the smaller its resistance will be. However, regardless of how wide a metal plate may be, the size of each pad that is bonded to a transistor remains constant. Therefore, in terms of resistance reduction, there is not much significance in sizing a metal plate so as to become wider than the outer shape of the transistor. Conversely, the increased width of the metal plate may result in enlarging of the outer shape of the power module. In this respect, it is preferable that, along the direction that is substantially perpendicular to the longitudinal direction thereof, each metal plate is one time to two times as wide as the outer shape of the corresponding transistor.

It is also preferable that the terminals a, b, C, d, and e satisfy the aforementioned conditions because a large current will flow therethrough. On the other hand, the control signal terminals 106U and 106L do not need to satisfy the aforementioned conditions because a large current will not flow therethrough. However, in the case where lead frames are used to produce the power modules 101, it would be preferable to form the control signal terminals 106U and 106L by using the same material as that of the first, second, and third metal plates 125, 126c to 126e, and 127 and/or the terminals a, b, c, d, and e, because in this case the control signal terminals 106U and 106L can be formed concurrently with the first, second, and third metal plates 125, 126c to 126e, and 127 and/or the terminals a, b, c, d, and e.

The size of the power module 101 will depend on the size and number (number of motor phases) of transistors used. Moreover, the size of each transistor will depend on the driving current, i.e., the rating of the motor to be driven. For example, in the case of driving a motor whose rating is 1 kW with a three phase current, the package of the power module 101 will have an outer shape of about 6 cm×3.5 cm×0.5 cm., for example.

In the power module according to the present preferred embodiment, electrical connections to the power semiconductor devices are realized by metal plates which are directly bonded. Therefore, as compared to a conventional power module in which wires are used, the power semiconductor devices can be electrically connected with a low resistance. As a result, heat loss at the electrical connections can be reduced, and an improved efficiency can be obtained. Since heating at the electrical connections is minimized, the temperature of power semiconductor devices under operation can be reduced. As a result, deterioration of the power semiconductor devices due to heat can be prevented, thus making for an improved reliability. Alternatively, if a temperature increase can be tolerated to the same degree as in the conventional case, it will be possible to allow a larger-than-conventional current to flow through the power semiconductor devices, thus enhancing the operating performance of the transportation apparatus which incorporates the power module according to one of the preferred embodiments of the present invention.

Moreover, by realizing electrical connections using metal plates, the inductance within the power module circuit can be reduced. As a result, the surge voltage which may occur when rapidly switching the power semiconductor devices can be reduced.

Moreover, since the metal plates can be bonded to the power semiconductor devices via soldering or the like, it is unnecessary to perform wire bonding using ultrasonic waves. As a result, damage to the power semiconductor devices due to wire bonding can be avoided. Since no wires are used, wire breaks due to vibration or the like can also be avoided. This feature will particularly contribute to the reduction of malfunctioning due to vibration, as well as reliability enhancement, in the case where the power module according to a preferred embodiment of the present invention is used for a transportation apparatus which is prone to vibrations.

Moreover, since the metal plates and the power semiconductor devices are covered within an integrally-molded package, the metal plates and the power semiconductor devices are in close contact with the package, so that the heat generated in the metal plates or the power semiconductor devices can be efficiently transmitted to the package. Therefore, by coupling a radiator or the like to the package, it becomes possible to allow the heat generated in the metal plates or the power semiconductor devices to be highly efficiently dissipated to the outside, thus minimizing deterioration of the power semiconductor devices and enhancing reliability. In particular, the power semiconductor devices are stacked so as not to overlie one another within the package. This prevents concentration of the heat generated in the power semiconductor devices due to overlapping of elements, and permits uniform radiation of the heat within the overall package. In other words, since there is substantially no local concentration of heat, malfunctioning and/or deterioration of the power semiconductor devices due to heat concentration is minimized, whereby the reliability of the overall power module is enhanced.

Moreover, in accordance with the power module of the present preferred embodiment, the component elements for as many phases as necessary for the motor driving can be accommodated in a single package. Therefore, when producing a motor control unit by using the power module, the number of parts of the motor control unit can be minimized, thus reducing the amount of time required for producing the motor control unit and making the outer shape of the motor control unit small.

Note that the positioning of the transistors and passive elements and the connected positions of the terminals a to e and 106U and 106L in the power module 101 shown in FIGS. 6A, 6B, and 6C are only exemplary. It will be appreciated that the positions of the transistors and passive elements and the connected positions of the terminals a to e and 106U and 106L may be different from those shown in FIGS. 6A, 6B, and 6C. For example, the terminals a and b may be connected to the third metal plate 127 and the first metal plate 125 at the positions shown by arrows A and B in FIG. 6A. In this case, the terminal a and the third metal plate 127 connected thereto are to be disposed so as to be substantially parallel to and overlap the terminal b and the first metal plate 125 connected thereto, with a predetermined distance therebetween. By adopting such a structure, a current flowing in the terminal a and the third metal plate 127 connected thereto will be in an opposite direction from that of a current flowing in the terminal b and the first metal plate 125 connected thereto. The opposite currents flowing through these terminals and metal plates are so close to each other that the inductances occurring due to these currents will cancel each other. As a result, the inductances associated with the electrical connections can be reduced.

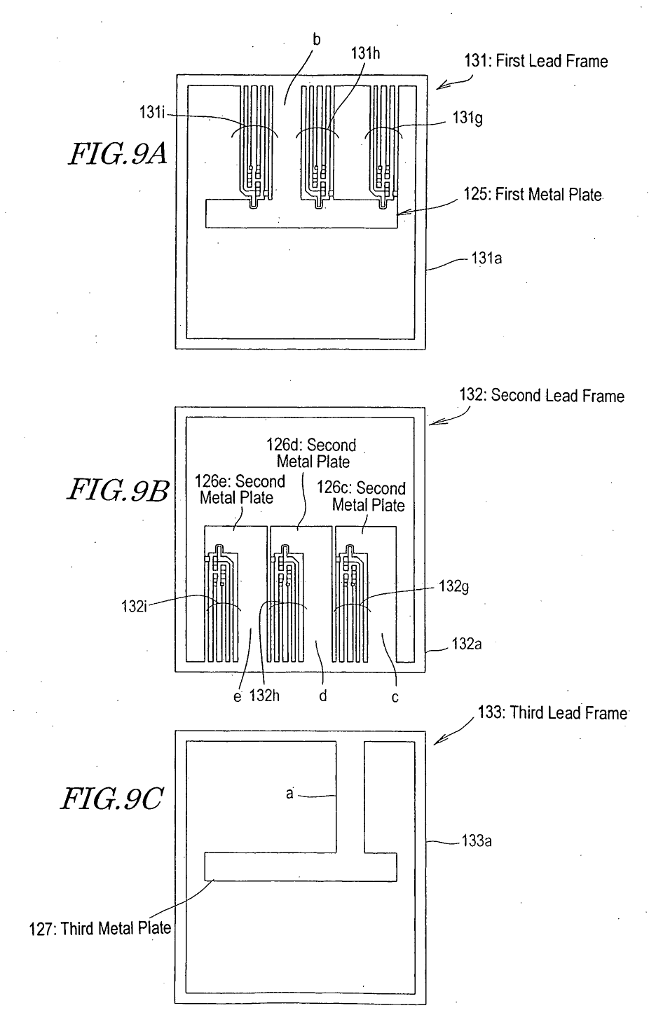

Furthermore, the number of metal plates and the shapes thereof may also be different from those of the first, second, and third metal plates 125, 126c to 126e, and 127 shown in FIGS. 9A, 9B, and 9C.

Next, an example of a motor control unit incorporating the power module 101 of the present preferred embodiment will be described with reference to FIG. 8. The motor control unit shown in FIG. 8 includes the above-described power module 101, a case 130, and a substrate 105 on which the control circuit is constructed. The power module 101 is attached in such a manner that the package thereof is in close contact with the surface 130a of the case 130. Since the package is composed of an insulative material, the power module 101 can be attached directly to the case 130, with no insulation substance being present between the case 130 and the power module 101.

The case 130 is preferably composed of a material having a high heat-releasing ability, e.g., aluminum, copper, or stainless steel. On the substrate 105, electronic components 105′ for composing the control circuit are mounted. The electronic components 105′ may be provided on one surface or both surfaces of the substrate 105. The control signal terminals 106U and 106L of the power module 101 are connected to the substrate 105. The terminals a and b are connected to a battery, whereas the terminals c, d, and e are connected to a motor.

In the motor control unit shown in FIG. 8, the heat generated in the power module 101 is directly dissipated from the package to the case 130. Therefore, the heat can be efficiently released to the outside, whereby an increase in the temperature of the power module 101 can be prevented.

Next, an exemplary method of producing the power module 101 will be described. First, a first lead frame 131, a second lead frame 132, and a third lead frame 133 as shown in FIGS. 9A to 9C are prepared.

As shown in FIG. 9A, the first lead frame 131 preferably includes a frame 131a, a terminal b connected to the frame 131a, and a first metal plate 125 connected to the terminal b. The first lead frame 131 further includes, as control signal terminals and terminals on which to mount passive elements, terminals 131g, 131h, 131i which are connected to the frame 131a. Each of the terminals 131g, 131h, and 131i is composed of four thread-like plates.

As shown in FIG. 9B, the second lead frame 132 preferably includes a frame 132a, terminals c, d, and e which are connected to the frame 132a, and second metal plates 126c, 126d, and 126e which are connected to the terminals c, d, and e, respectively. Moreover, as control signal terminals and terminals on which to mount passive elements, the second lead frame 132 further includes terminals 132g, 132h, and 132i which are connected to the frame 132a, as in the case of the first lead frame 131. Each of the terminals 132g, 132h, and 132i is preferably composed of four thread-like plates, as are the terminals 131g, 131h, and 131i.

As shown in FIG. 9C, the third lead frame 133 preferably includes a frame 133a, a terminal a connected to the frame 133a, and a third metal plate 127 connected to the terminal a.

Each of these three lead frames is preferably obtained by patterning a substantially rectangular-shaped metal plate, via stamping, etching, electro-discharge machining, or other suitable process. It is preferable that the frames 131a, 132a, and 133a of the respective lead frames are formed to have an identical shape or substantially identical shape because the leads connected to each frame are to be positioned based on frame positioning. Moreover, the positions of the metal plates and the terminals with respect to each frame are selected so that the metal plates and the terminals will be in place when the frames of the lead frames are disposed in overlapping positions with one another. Although a case is illustrated where the first metal plate 125, the second metal plates 126c to 126e, and the third metal plate 127 are connected to the respective frames via the terminal b, terminals c, d, and e, and the terminal a, it will be appreciated that these metal plates may be connected to each frame via connection rims which are provided separately from the terminals.

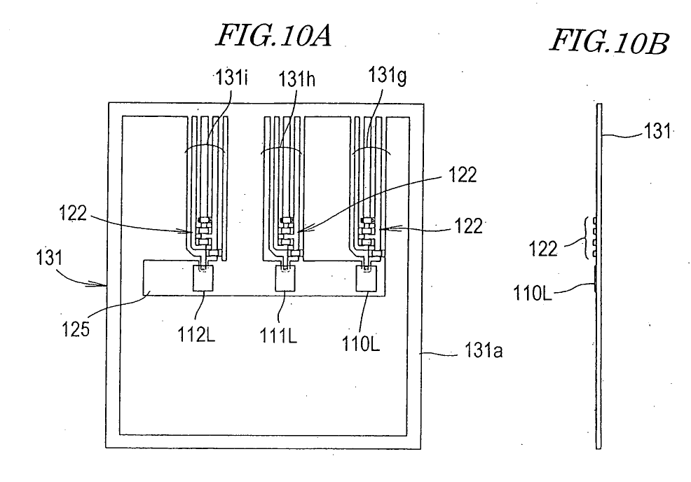

By using these three lead frames, the production of the power module 101 will be performed as follows. First, as shown in FIGS. 10A and 10B, transistors 110L, 111L, and 112L are affixed (permanently or temporarily) to predetermined positions on the first metal plate 125 included in the first lead frame 131, preferably by using solder paste, for example. At this time, passive elements 122 are also affixed (permanently or temporarily) to predetermined positions on the terminals 131g, 131h, and 131i. Instead of solder paste, a conductive adhesive may be used for the affixation.

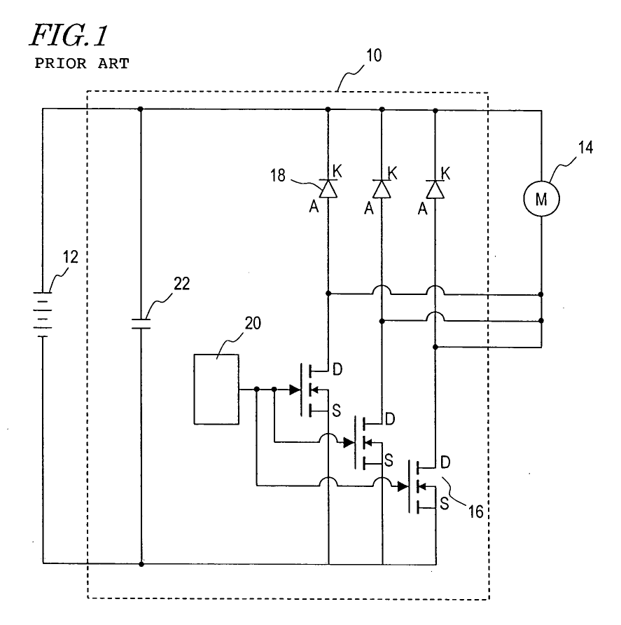

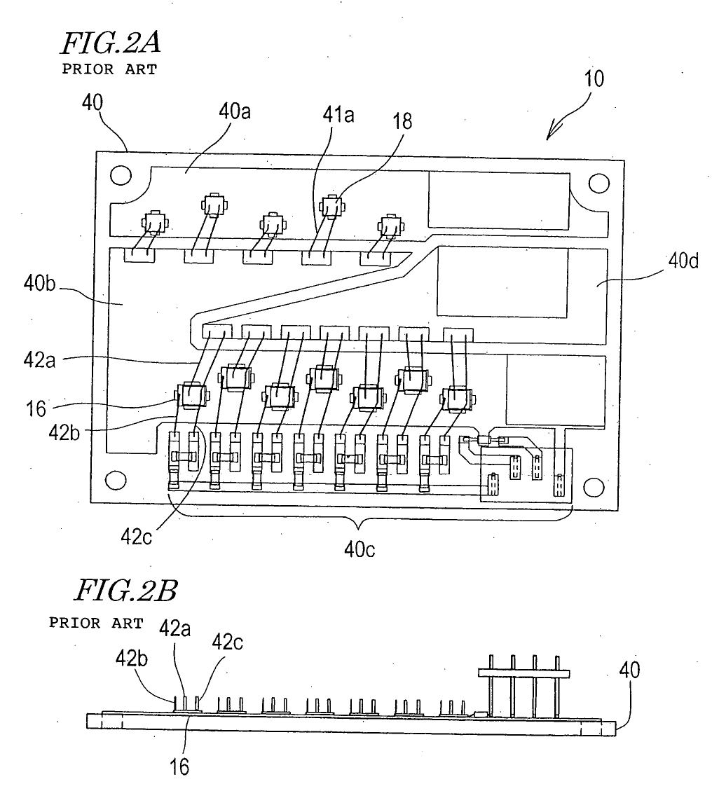

In this step, the source pads SP of the transistors 110L, 111L, and 112L are positioned so as to be bonded to the first metal plate 125. To the gate pads GP of the transistor 110L, 111L, or 112L, an end of one of the four thread-like plates of the terminal 131g, 131h, or 131i is aligned, respectively. At this time, care must be taken so that the aforementioned thread-like plate of each terminal is not in contact with the source pad SP. For example, as shown in FIG. 11A, a bump 134 may be formed on the gate pad GP, and a bent portion 136 for accommodating the height of the bump 134 may be provided near the tip of the terminal 131g. Then, the terminal 131g and the bump 134 may be temporarily affixed with solder paste 139, and the metal plate 125 and the source pad SP may be temporarily affixed with solder paste 139. Alternatively, as shown in FIG. 11B, an arched bent portion 137 may be provided in the terminal 131g so as to prevent the terminal 131g from coming in contact with the source pad SP. Moreover, as shown in FIG. 1C, any region of the terminal 131g other than the region which must be in contact with the gate pad GP may be covered with an insulating film 135.

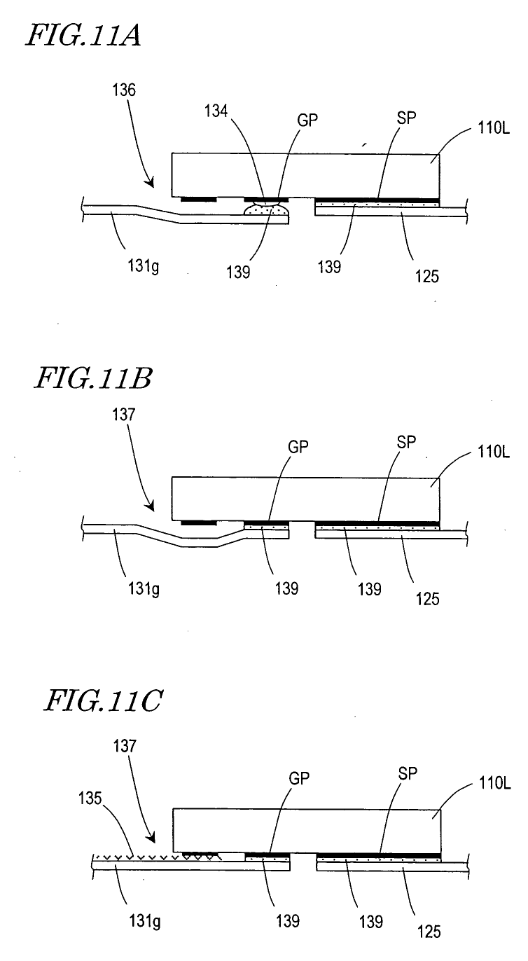

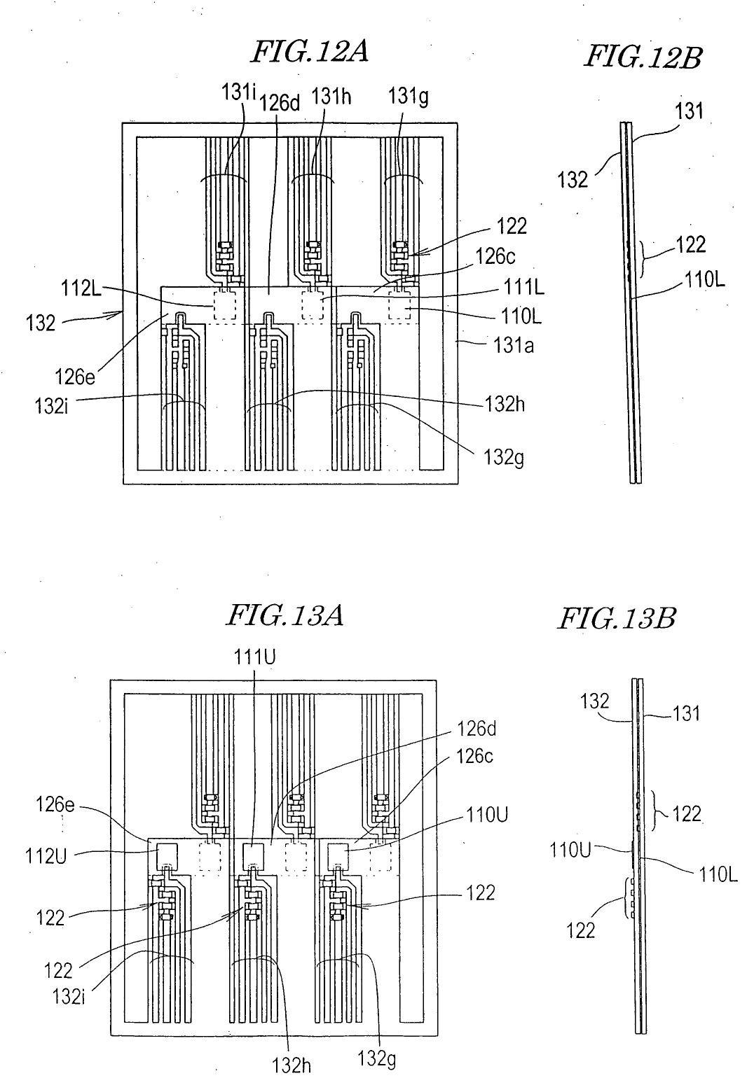

Next, as shown in FIGS. 12A and 12B, the second lead frame 132 is overlaid on the first lead frame 131, with solder paste being applied on the drain pads DP of the transistors 110L, 111L, and 112L. By positioning the second lead frame 132 and the first lead frame 131 so that the frame 132a of the second lead frame 132 overlaps the frame 131a of the first lead frame 131, it is ensured that the second metal plates 126c, 126d, and 126e and terminals 132g, 132h, and 132i of the second lead frame 132 are placed in appropriate positions with respect to the first metal plate 125 and the transistors 110L, 111L, and 112L.

Next, as shown in FIGS. 13A and 13B, transistors 110U, 111U, and 112U are affixed (permanently or temporarily) to predetermined positions on the second metal plates 126c, 126d, and 126e, in a manner similar to the above. At this time, passive elements 122 are also permanently or temporarily affixed to predetermined positions on the terminals 132g, 132h, and 132i.

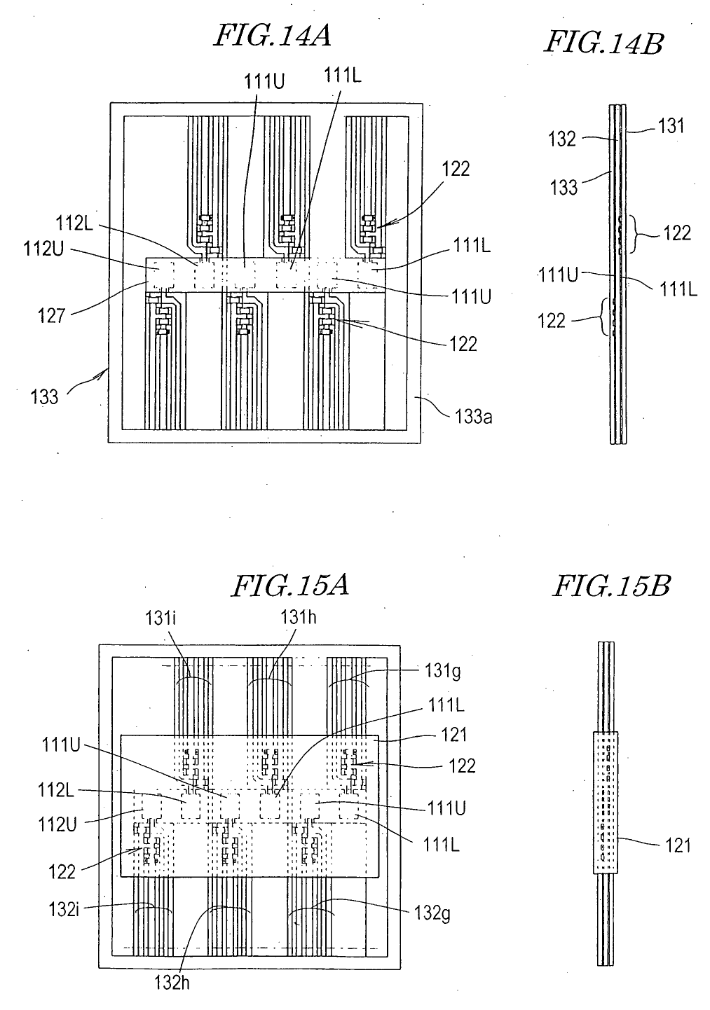

Next, solder paste is applied on the drain pads DP of the transistors 110U, 111U, and 112U, and as shown in FIG. 14, the third lead frame 133 is overlaid on the second lead frame 132. By positioning the third lead frame 133 and the second lead frame 132 so that the frame 133a of the third lead frame 133 overlaps the frame 132a of the second lead frame 132, it is ensured that third metal plate 127 of the third lead frame 133 is located in an appropriate position with respect to the second metal plates 126c, 126d, and 126e and the transistors 110U, 111U, and 112U.

Next, the stacked lead frames are placed in a reflow oven. After the solder is melted, the lead frames are allowed to cool within the reflow oven, thus permitting the solder to solidify. Furthermore, as shown in FIGS. 15A and 15B, the lead frames are held in a die for accommodating the metal plates, transistors, and passive elements, and a molding is performed, preferably by using a thermosetting resin, so as to cover these elements. As a result, the package 121 is completed. The molding is preferably performed at a temperature at which solder does not melt. Note that the reflow process is unnecessary in the case where a conductive adhesive is used instead of solder paste.

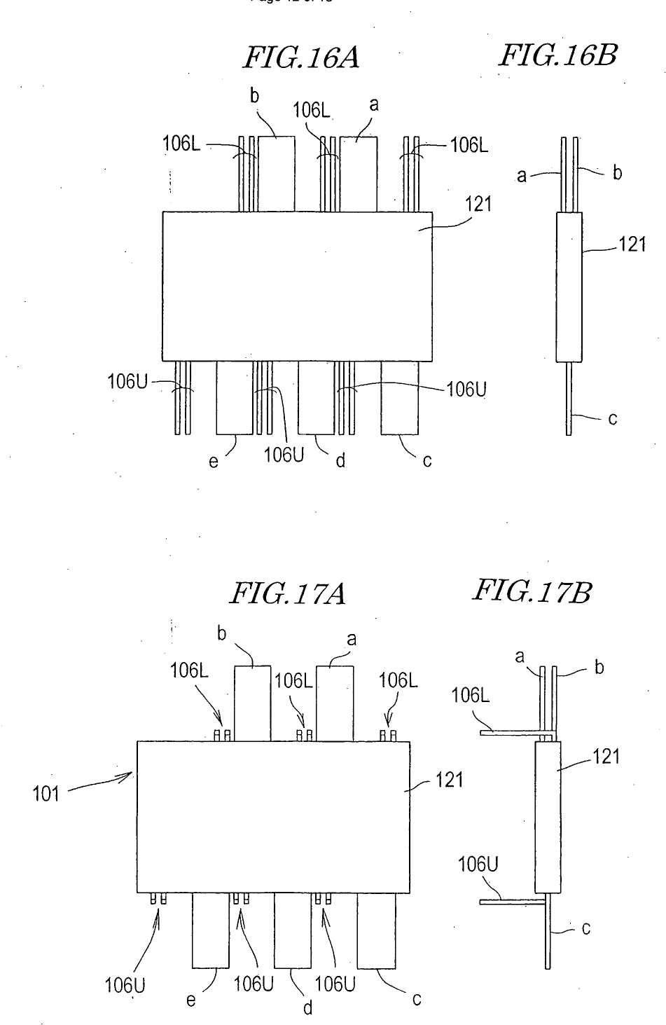

Thereafter, the frames are cut off as shown in FIGS. 16A and 16B. Note that, out of the four thread-like plates defining each of the terminals 131g, 131h, and 131i and the terminals 132g, 132h, and 132i, two are used only for the interconnection between the passive elements, and those two do not need to be led outside the package as terminals. Therefore, those two thread-like plates are cut in accordance with the outer shape of the package. This results in the terminals 106L and 106U composed of the remaining two thread-like plates. Finally, as shown in FIGS. 17A and 17B, the terminals 106L and 106U are bent, whereby the power module 101 is completed.

In accordance with the above production method, the frames of the lead frames can be aligned easily and highly accurately because the lead frames have an identical outer shape. Thus, highly accurate alignment can be realized between the metal plates connected to the respective frames. Since the frames are of an identical shape, it is also possible to realize highly accurate positioning of any apparatus to be used in a step such as mounting of the power semiconductor devices, stacking of the lead frames, or mold resin processing of the stacked lead frames being set in a die. The identical outer shape also provides for good workability.

Moreover, insulation between the power semiconductor devices, the metal plates, and the passive elements can be achieved through an integral mold resin processing which is performed after stacking all of the metal plates. As a result, highly reliable insulation structures can be formed at once, and the production cost can be reduced.

Next, an embodiment of the transportation apparatus according to the present invention will be described.

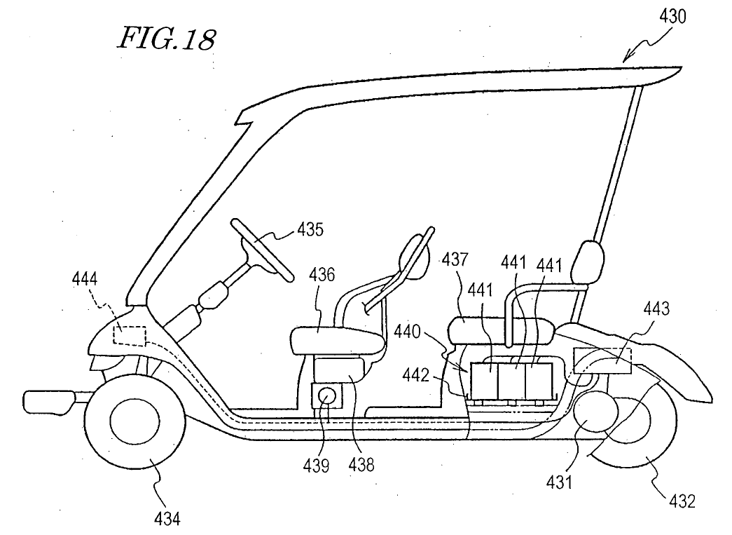

FIG. 18 shows an electric vehicle 430 according to the present preferred embodiment. The illustrated electric vehicle 430 is preferably a cart which is suitably used for transporting luggage (e.g., golf bags) and people on a golf course, for example. Although FIG. 18 exemplifies a four-wheeled electric vehicle, the transportation apparatus may alternatively be a two-wheeled vehicle such as an electric motorcycle. Other than an electric vehicle, the transportation apparatus may be any transportation apparatus for carrying luggage and people which is run by a motor defining a driving or propulsion mechanism.

The electric vehicle 430 of the present preferred embodiment includes a driving motor 431, two rear wheels 432 which are driven by the driving motor 431, and front wheels 434 which are steered manually or automatically. The driving force from the driving motor 431 is transmitted to the rear wheels 432 via a transmission (not shown). The front wheels 434 are steered through manual or automatic operation of a steering wheel 435.

A front seat 436 and a rear seat 437 are preferably provided at the front and rear compartments of the cart. Below the front seat 436, a charging controller 438 and a brake motor 439 are provided. Below the rear seat 437, a driving battery device 440 which defines a power source for the driving motor 431 is provided. The driving battery device 440 preferably includes a total of six batteries 441, for example, which are in series connection (out of which only three batteries 441 mounted on one side of the cart are shown in FIG. 18). The batteries 441 are placed on a keeper 442 with interspaces provided therebetween.

Above the driving motor 431, a controller 443 for drive control is provided. The controller for drive control 443 is connected to the driving battery device 440, the driving motor 431, the brake motor 439, and a steering motor 444 for controlling these devices. The controller for drive control 443 and the driving motor 431 are placed between the two rear wheels 432.

The power module 101 is installed in the interior of the controller for drive control 443, receives a DC current supplied from the battery 440, and converts the DC current into an AC current. The AC current from the power module 101 is supplied to the driving motor 431, the brake motor 439, and the steering motor 444.

According to the present preferred embodiment, by mounting a power module having a high reliability or high power capabilities on an electric vehicle, an electric vehicle is realized which has a high reliability or a high driving performance.

The present invention is suitable for a power module which handles a large current, and is particularly suitably used for a power module which supplies an extremely large current (e.g., about 30 A or more). The power module according to preferred embodiments of the present invention is suitably used for a transportation apparatus whose driving mechanism is a motor.

While the present invention has been described with respect to preferred embodiments thereof, it will be apparent to those skilled in the art that the disclosed invention may be modified in numerous ways and may assume many embodiments other than those specifically described above. Accordingly, it is intended by the appended claims to cover all modifications of the invention that fall within the true spirit and scope of the invention.

This application is based on Japanese Patent Application No. 2004-221170 filed on Jul. 29, 2004, the entire contents of which are hereby incorporated by reference.

What is claimed is:

1. A power module comprising:
a plurality of first semiconductor devices arranged to define a first layer in a substantially common plane;
a plurality of second semiconductor devices arranged to define a second layer in a substantially common plane; and
at least one metal plate electrically connected to at least two semiconductor devices selected from among the plurality of first and second semiconductor devices; wherein
the first layer and second layer are stacked in such a manner that the plurality of second semiconductor devices do not overlap the plurality of first semiconductor devices.

2. The power module of claim 1, wherein,
the at least one metal plate includes first, second, and third metal plates; and
the first, second, and third metal plates are arranged such that the plurality of first semiconductor devices defining the first layer are interposed between the first and second metal plates, and such that the plurality of second semiconductor devices defining the second layer are interposed between the second and third metal plates.

3. The power module of claim 2, wherein the first, second, and third metal plates are made of a material selected from the group consisting of copper, aluminum, and stainless steel.

4. The power module of claim 2, wherein the first and second semiconductor devices are arranged to alternate on a surface of projection that is substantially perpendicular to a direction in which the first layer and the second layer are stacked.

5. The power module of claim 2, wherein,
the second metal plate is connected, on a front surface thereof, to at least one of the plurality of first semiconductor devices; and
the second metal plate is connected, on a back surface thereof, to at least one of the plurality of second semiconductor devices.

6. The power module of clam 2, further comprising a package for enclosing the first, second, and third metal plates and the plurality of first and second semiconductor devices in an integral manner.

7. The power module of claim 2, wherein,
each of the plurality of first and second semiconductor devices includes a plurality of pads for establishing external electrical connections; and
the plurality of pads include a large current pad to or from which a large current is applied or taken out, and a control signal pad to which a control signal is applied, the large current pad being connected to the first, second, or third metal plate.

8. The power module of claim 7, further comprising a large current terminal connected to the first, second, or third metal plate, and a control signal terminal connected to the control signal pad.

9. The power module of claim 8, further comprising a passive element electrically connected to the control signal terminal.

10. The power module of claim 2, wherein the first, second, and third metal plates have a thickness in a range from about 0.5 mm to about 2 mm.

11. The power module of claim 1, wherein the plurality of first and second semiconductor devices are a plurality of MOS-FETs.

12. The power module of claim 11, wherein the plurality of first semiconductor devices are three first semiconductor devices, the plurality of second semiconductor devices are three second semiconductor devices, and the power module constitutes a three-phase inverter circuit for driving a motor.

13. A motor control unit comprising:
the power module of claim 1; and
a control circuit arranged to output a control signal to the plurality of first and second semiconductor devices.

14. An electric transportation apparatus comprising:
the motor control unit of claim 13;
a motor connected to the motor control unit; and
a battery arranged to supply power to the motor control unit.

15. A method of producing a power module, the method comprising the following steps:
(A) affixing a plurality of first semiconductor devices each having a pad on an upper surface and a pad on a lower surface for establishing external electrical connections, to a first lead frame having a frame to which a first metal plate is connected, such that one of the pad on the upper surface and the pad on the lower surface is in contact with the first metal plate;
(B) affixing a second lead frame having a frame to which a second metal plate is connected, to the plurality of first semiconductor devices, such that the other of the pad on the upper surface and the pad on the lower surface of each of the plurality of first semiconductor devices is in contact with the second metal plate;
(C) placing a plurality of second semiconductor devices each having a pad on an upper surface and a pad on a lower surface for establishing external electrical connections, on a surface of the second metal plate to which the plurality of first semiconductor devices are not bonded, such that the plurality of second semiconductor devices do not overlap the plurality of first semiconductor devices, and affixing the plurality of second semiconductor devices such that one of the pad on the upper surface and the pad on the lower surface is in contact with the second metal plate;
(D) affixing a third lead frame having a frame to which a third metal plate is connected, to the plurality of second semiconductor devices, such that the other of the pad on the upper surface and the pad on the lower surface of each of the plurality of second semiconductor devices is in contact with the third metal plate; and
(E) cutting the first, second, and third metal plates off of the corresponding frames.

16. The power module producing method of claim 15, wherein,
the frames of the first, second, and third lead frame have an identical shape; and
by aligning the frames of the first, second, and third lead frames with one another, the first, second, and third metal plates are positioned with respect to the plurality of first and second semiconductor devices.

17. The power module producing method of claim 15, wherein,
in steps (A), (B), (C), and (D), the affixing steps are performed by using solder paste; and
between step (D) and step (E), the method further comprises step (F) of performing a heat treatment to melt and solidify the solder paste.

18. The power module producing method of claim 17, wherein, between step (F) and step (E), the method further comprises step (G) of forming via molding a package enclosing the first, second, and third metal plates and the plurality of first and second semiconductor devices in an integral manner.

19. The power module producing method of claim 15, wherein,
the pads of each of the plurality of first and second semiconductor devices include a large current pad to or from which a large current is applied or taken out, and a control signal pad to which a control signal is applied; and
at least one of the first, second, and third lead frames include a control signal terminal which is connected to the frame so as to be connected to the control signal pad.

20. The power module producing method of claim 19, wherein a bump is formed on the control signal pad, and the bump is connected to the control signal terminal.

21. The power module producing method of claim 19, wherein the control signal terminal includes an insulating film covering any region other than a region arranged to be in contact with the control signal pad.
